(19) United States
(12) Patent Application Publication
(10) Pub. No.: US 2012/0302047 A1
(43) Pub. Date: Nov. 29, 2012

(54) METHOD FOR FABRICATING SEMICONDUCTOR DEVICE WITH PARTIALLY OPEN SIDEWALL

(76) Inventors: Mi-Ri LEE, Gyeonggi-do (KR); Jae-Geun Oh, Gyeonggi-do (KR); Seung-Joon Jeon, Gyeonggi-do (KR); Jin-Ku Lee, Gyeonggi-do (KR); Bong-Seok Jeon, Gyeonggi-do (KR)

(21) Appl. No.: 13/230,931

(22) Filed: Sep. 13, 2011

(30) Foreign Application Priority Data
May 24, 2011 (KR) 10-2011-0049237

(51) Int. Cl. H01L 21/265

(52) U.S. Cl. 438/482; 257/E21.335

(57) ABSTRACT

A method for fabricating a semiconductor device includes forming a structure having first surfaces at a height above a second surface, which is provided between the first surfaces, forming a first silicon layer on the structure, performing a tilt ion implantation process on the first silicon layer to form a crystalline region and an amorphous region, forming a second silicon layer on the amorphous region, removing the second silicon layer and the first silicon layer until a part of the second surface is exposed, thereby forming an etch barrier, and etching using the etch barrier to form an open part that exposes a part of a sidewall of the structure.

### CROSS-REFERENCE TO RELATED APPLICATIONS

The present application claims priority of Korean Patent Application No. 10-2011-0049237, filed on May 24, 2011, which is incorporated herein by reference in its entirety.

### BACKGROUND

1. Field of the Invention

Exemplary embodiments of the present invention relate to a method for fabricating a semiconductor device, and more particularly, to a method for fabricating a semiconductor device with a partially open sidewall.

2. Description of the Related Art

In a method for opening a specific part (for example, a contact region) of a semiconductor device fabrication process, a mask using a photoresist layer and an etching method are mainly used. As a semiconductor device becomes more highly integrated, a more complicated three-dimensional structure is formed, and thus, a mask process using a photoresist layer is required to be more and more precise. However, a mask using a photoresist layer and an etching method have reached a limit in a dynamic random access memory (DRAM) below 20 nm.

Specifically, in a process for exposing a part of a sidewall in a three-dimensional structure such as a pillar with a high aspect ratio, there is a limitation in applying conventional photolithography equipment.

Recently, in order to form an etch barrier to replace a photoresist layer, a method using polysilicon has been proposed.

For example, a pillar with a high aspect ratio is formed and polysilicon is formed on the pillar. A doped region and an undoped region are formed in the polysilicon through an ion implantation process. The undoped region is selectively removed using the etching rate difference between the doped region and the undoped region, and lower materials between pillars are etched using the remaining doped region as an etch barrier.

However, in order to use the etching rate difference between the doped region and the undoped region, ion implantation energy and ion implantation dose are adjusted. To this end, an ion implantation process should be performed at least two times, and the thickness of the polysilicon should be substantially equal to or more than a predetermined thickness. But, an interval between pillars is reduced, thus making it difficult to selectively implant ions at a desired region.

### SUMMARY

Exemplary embodiments of the present invention are directed to a method for fabricating a semiconductor device, which is capable of easily performing a process for exposing a part of a sidewall of a three-dimensional structure with a high aspect ratio.

In accordance with an exemplary embodiment of the present invention, a method for fabricating a semiconductor device includes forming a first silicon layer including an amorphous region and a crystalline region, forming a second silicon layer on one of the amorphous region and the crystalline region through a selective epitaxial growth process, and removing the second silicon layer and the first silicon layer until one of the regions of the first silicon layer is removed.

In accordance with another exemplary embodiment of the present invention, a method for fabricating a semiconductor device includes forming a structure having first surfaces at a height above a second surface, which is provided between the first surfaces, forming a first silicon layer on the structure, performing a tilt ion implantation process on the first silicon layer to form a crystalline region and an amorphous region, forming a second silicon layer on the amorphous region, removing the second silicon layer and the first silicon layer until a part of the second surface is exposed, thereby forming an etch barrier, and etching using the etch barrier to form an open part that exposes a part of a sidewall of the structure.

### BRIEF DESCRIPTION OF THE DRAWINGS

FIGS. 1A and 1B are diagrams illustrating a semiconductor device in accordance with an exemplary embodiment of the present invention.

FIGS. 2A to 2L are cross-sectional views illustrating a method for fabricating a semiconductor device in accordance with an exemplary embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate, but also a case where a third layer exists between the first layer and the second layer or the substrate.

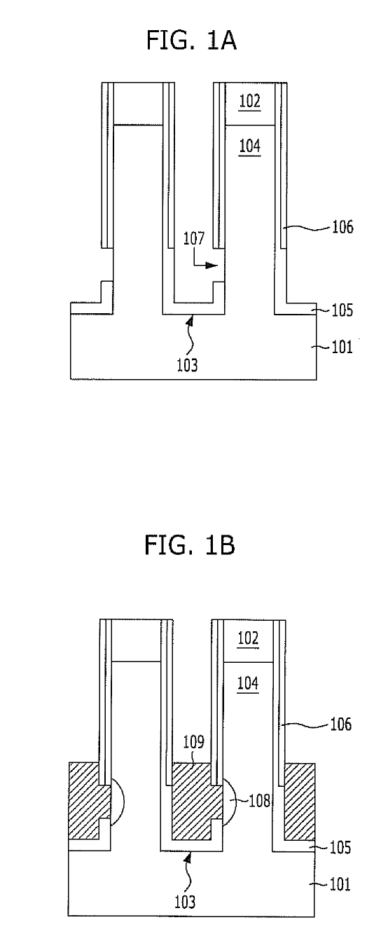

FIGS. 1A and 1B are diagrams illustrating a semiconductor device in accordance with an exemplary embodiment of the present invention.

Referring to FIG. 1A, a plurality of bodies 104 separated by a plurality of trenches 103 are formed on a substrate 101. The substrate 101 includes a silicon substrate. Since the substrate 101 includes a silicon substrate, each of the bodies 104 is a silicon body. The bodies 104 vertically extend from the surface of the substrate 101. The bodies 104 may be used as active regions. As well known in the art, in an active region, a channel, a source, and a drain of a transistor are formed. Each of the bodies 104 has sidewalls. More specifically, because the bodies 104 are formed from trenches 103, each of the bodies 104 is a line-type pillar with at least two opposite sidewalls, which extend vertically from the substrate 101 and are approximately parallel to one another. Herein, the body 104 may also be called an ‘active body’.

A hard mask layer 102 is formed on the bodies 104. An insulation layer (105 and 106) covers inner surfaces of each of the trenches 103, except for an open part 107. That is, the insulation layer is formed on both sidewalls of each of the bodies 104, the bottom surfaces of the trenches 103 between the bodies 104, and sidewalls of the hard mask layer 102. The insulation layer may include a liner oxide layer 105 and a liner nitride layer 106. The liner oxide layer 105 is formed on both sidewalls of the bodies 104 and the exposed surfaces of the substrate 101 (i.e., the bottom surfaces of the trenches 103). The liner nitride layer 106 is formed on a part of the surface of the liner oxide layer 105. The open part 107 for exposing a part of one sidewall of each of the bodies 104 is provided by the above-mentioned insulation layer, and a junction 108 is formed in a portion of the sidewall of the body 104 exposed by the open part 107.

Referring to FIG. 1B, buried bit lines 109, which fill bottom portions of the trenches 103 and the open part 107 while making contact with the junction 108, are formed. That is, each of the buried bit lines 109 partially fills one of the trenches 103. The buried bit line 109 may be formed of a low resistance material. For example, the buried bit line 109 includes a metal layer or a metal nitride layer. More specifically, the buried bit line 109 may include a titanium nitride (TiN) layer.

The semiconductor device illustrated in FIGS. 1A and 1B requires the open part 107 for a contact between the buried bit line 109 and the junction 108. The open part 107 exposes a part of the lower sidewall of a respective body 104, which is a three-dimensional structure. Since the open part 107 exposes a part of the sidewall of the body 104, the open part 107 is also called a sidewall open part or a side contact. In addition, since the open part 107 exposes a part of only one sidewall of the body 104, the open part 107 is also called a one side contact (OSC).

Hereinafter, an etch barrier formation method and an open part formation method using the same will be described.

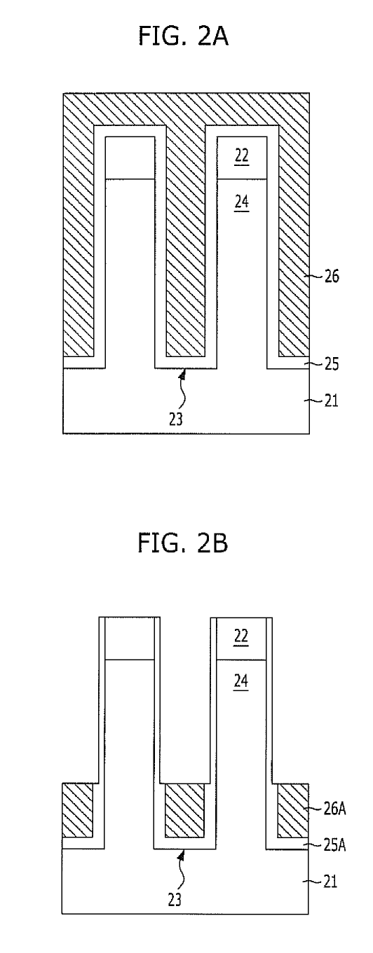

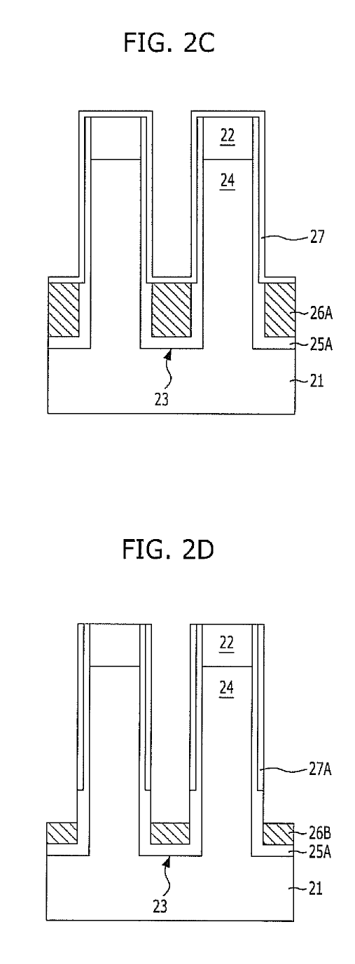

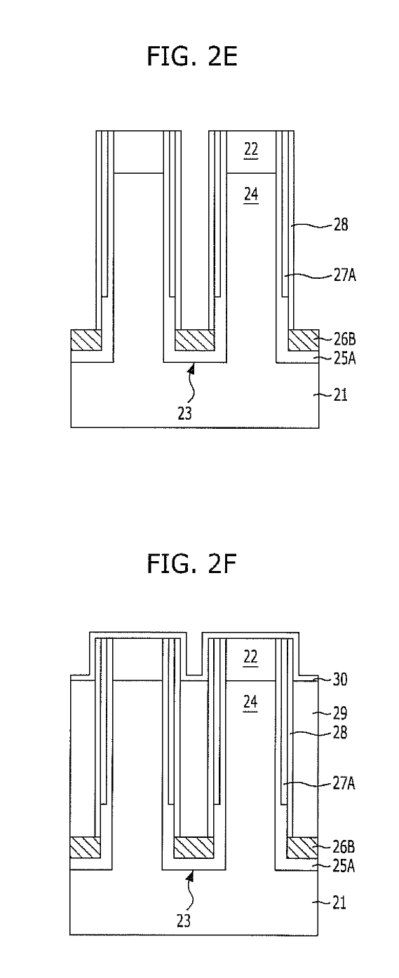

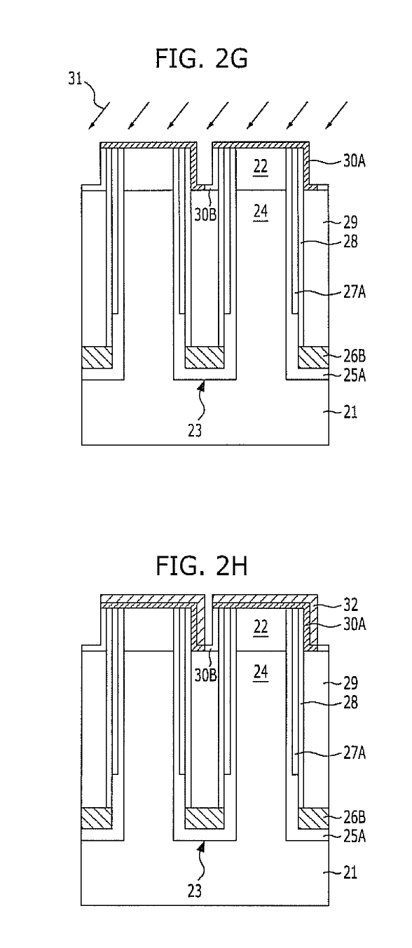

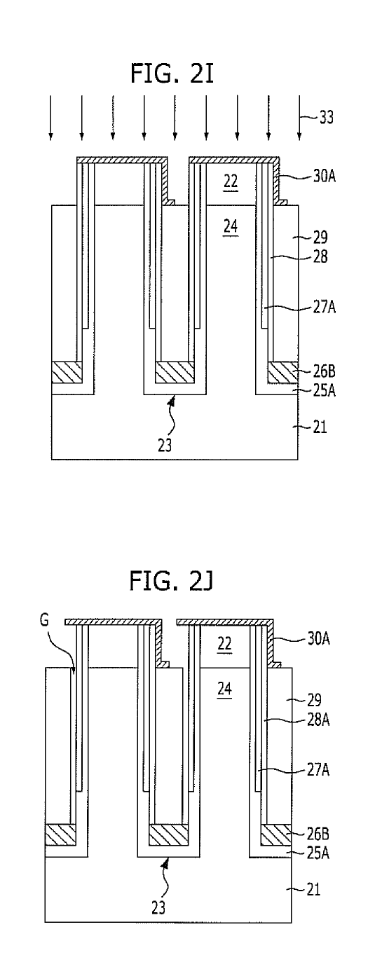

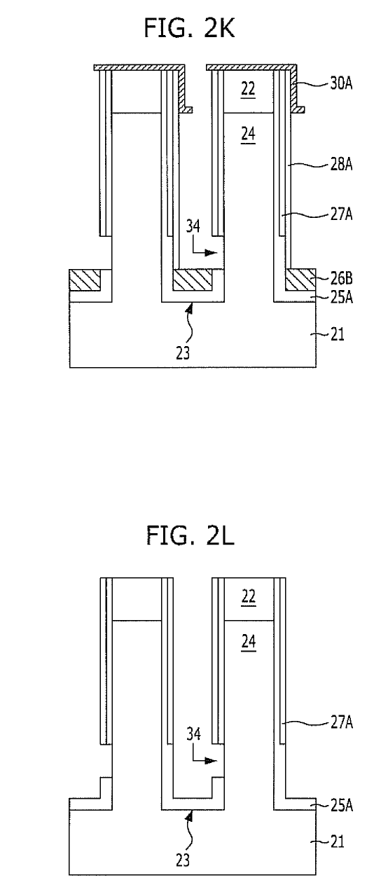

FIGS. 2A to 2L are cross-sectional views illustrating a method for fabricating a semiconductor device in accordance with an exemplary embodiment of the present invention.

Referring to FIG. 2A, a hard mask layer 22 is formed on a substrate 21. The substrate 21 may be a silicon substrate. The hard mask layer 22 may include a nitride layer. The hard mask layer 22 may have a multilayer structure including an oxide layer and a nitride layer. For example, the hard mask layer 22 may have a structure in which a hard mask nitride layer and a hard mask oxide layer are sequentially stacked. Furthermore, the hard mask layer 22 may have a structure in which a hard mask nitride layer, a hard mask oxide layer, a hard mask silicon oxynitride (HM SiON) layer, and a hard mask carbon layer are sequentially stacked. In the case of including the hard mask nitride layer, a pad oxide layer may be further formed between the substrate 21 and the hard mask layer 22. The hard mask layer 22 may be patterned using a photoresist pattern (not illustrated). More specifically, the hard mask layer 22 may be patterned to form a line-type pattern in which the hard mask layer 22 is separated into a plurality of parallel line-shaped structures having a gap therebetween.

A trench etch process is performed using the hard mask layer 22 as an etch barrier. For example, the substrate 21 is etched by a predetermined depth using the hard mask layer 22 as an etch barrier to form bodies 24. The bodies 24 are separated by the trenches 23. Each body 24 includes an active region where a transistor is to be formed. In the active region, a channel, a source, and a drain of the transistor are formed. Each body 24 has sidewalls. More specifically, each body 24 is a line-type pillar with at least two opposite sidewalls, which extend vertically from the substrate 21 and are approximately parallel to one another. Herein, the body 24 may also be called an ‘active body’.

The trench etch process includes an anisotropic etch process. When the substrate 21 is a silicon substrate, the anisotropic etch process may use Cl₂ or HBr gas separately, or include a plasma dry etch process using a mixture of these gases. A plurality of bodies 24 are formed on the substrate 21 by the above-mentioned trench 23.

A first liner layer 25 is formed on a resultant structure including the bodies 24 and functions as an insulation layer. The first liner layer 25 includes an oxide layer such as a silicon oxide layer. Further, as shown in FIG. 2A, the first liner layer is a relatively thin layer that lines the surfaces of the resultant structure.

A first sacrificial layer 26 is formed on the first liner layer 25 to gap-fill the trenches 23 between the bodies 24. The first sacrificial layer 26 includes undoped polysilicon or amorphous silicon.

Referring to FIG. 2B, the first sacrificial layer 26 is planarized until the surface of the hard mask layer 22 is exposed. The planarization of the first sacrificial layer 26 may be performed using a chemical mechanical polishing (CMP) process. Subsequently, an etch-back process is performed to etch the first sacrificial layer. As shown in FIG. 2B, the first sacrificial layer 26 may be etched back so that it only fills lower portions of the trenches 23. After the etch-back process is performed, a first sacrificial pattern 26A is formed. The back process includes a dry etch. In the chemical mechanical polishing process, the first liner layer 25 on the hard mask layer 22 may be polished. In this regard, a first liner pattern 25A is formed to cover both sidewalls of the hard mask layer 22 and the trench 23. The first liner pattern 25A also covers the bottom of the trench 23.

The first liner pattern 25A is subject to slimming using a wet etch process. At this time, a wet etch time is adjusted, so that the first liner pattern 25A with a particular thickness remains on the sidewalls of the body 24.

Referring to FIG. 2C, a second liner layer 27 is formed on a resultant structure, including the first sacrificial pattern 26A, to serve as an insulation layer. The second liner layer 27 may include a nitride layer such as a polysilicon nitride layer. The second liner layer 27 may have a thickness substantially the same as the thickness of the first liner pattern 25A. Further, the second liner layer 27 may have a thickness substantially equivalent to the thickness of the first liner layer that was removed during the slimming.

Referring to FIG. 2D, the second liner layer 27 is selectively etched. Thus, a second liner pattern 27A is formed on a slimmed region of the first liner pattern 25A. In order to form the second liner pattern 27A, an etch-back process may be used, and thus the second liner pattern 27A is provided in the form of a spacer.

The first sacrificial pattern 26A is recessed by a particular depth using the second liner pattern 27A as an etch barrier. Thus, a part of the surface of the first liner pattern 25A is exposed. The first sacrificial pattern 26A after being recessed is indicated by reference numeral ‘26B’. When the first sacrificial pattern 26B includes polysilicon, it is recessed using an etch-back process.

Referring to FIG. 2E, a second sacrificial layer is conformally formed on a resultant structure. The second sacrificial layer may include a metal nitride layer such as a titanium nitride (TiN) layer. A spacer etch process is performed to form a second sacrificial pattern 28 in the form of a spacer. The second sacrificial pattern 28 covers the second liner pattern 27A on both sidewalls of the body 24, and also covers an exposed portion of the first liner pattern 25A.

Referring to FIG. 2F, a third sacrificial pattern 29 is formed to gap-fill the trench 23, including the second sacrificial pattern 28 formed therein. The third sacrificial pattern 29 may include an oxide layer. For example, the third sacrificial pattern 29 may include a spin-on dielectric (SOD) layer. In order to form the third sacrificial pattern 29, an oxide layer is deposited and planarized, and an etch-back process is performed. Through such a series of processes, the third sacrificial pattern 29, recessed to have a surface lower than the hard mask layer 22, is formed.

As described above, the third sacrificial pattern 29 is formed, so that a stepped portion with a certain height is formed between the third sacrificial pattern 29 and the hard mask layer 22. For example, the top surface of the hard mask layer 22 is at a height above the top surface of the third sacrificial pattern 29.

A third liner layer 30 is formed on a resultant structure including the third sacrificial pattern 29. The third liner layer 30 may include a silicon layer. The third liner layer 30 may include undoped polysilicon with no impurity. Preferably, the third liner layer 30 is formed with a thickness of 100 Å or less.

Referring to FIG. 2G, a tilt ion implantation process 31 is performed.

In the tilt ion implantation process 31, dopant is implanted at a particular tilt angle. Dopant is implanted into a part of the third liner layer 30.

The tilt ion implantation process 31 may be performed at a predetermined tilt angle with respect to the vertical direction of the substrate surface. For example, the predetermined tilt angle may be in the range of about 5° to about 90°. A part of an ion beam is shadowed by the hard mask layer 22. Thus, a part of the third liner layer 30 is doped, but a remaining part of the third liner layer 30 remains undoped. For example, ion-implanted dopant includes P-type dopant and may include boron (B). In order to implant the boron, BF₂ is used as a dopant source.

Through the tilt ion implantation process 31, a part of the third liner layer, which is formed on the upper surface of the hard mask layer 22, and a part of the third liner layer, which is adjacent to the right side of the hard mask layer 22, become a doped region 30A doped with dopant. Also, as a result of the angle, a part of the third liner layer 30, which is adjacent to the left side of the hard mask layer 22, is not exposed to the tilt ion implantation process 31, and therefore, remains undoped. The third liner layer with no dopant becomes an undoped region 30B. Accordingly, a difference in crystallization exists between the doped region 30A and the undoped region 30B. That is, the crystallization of a silicon layer changes when it undergoes the tilt ion implantation process 31. For example, the doped region 30A, on which the tilt ion implantation process 31 has been performed, becomes amorphous, and the undoped region 30B remains crystalline. The polysilicon used for the third liner layer 30 becomes amorphous because silicon lattices thereof are destroyed by the ion implantation. The poly-crystallization of a part, on which the ion implantation process has not been performed, is preserved as is.

Hereinafter, the doped region 30A may be referred to as an ‘amorphous region 30A’ and the undoped region 30B may be referred to as a ‘crystalline region 30B’.

Referring to FIG. 2H, a selective growth process is performed, so that a fourth liner layer 32 is grown on the amorphous region 30A. The selective growth process uses a selective epitaxial growth (SEG) process. Since the amorphous region 30A and the crystalline region 30B include polysilicon, the fourth liner layer 32 becomes a silicon layer. That is, an epitaxial silicon layer is grown through the selective epitaxial growth process. In the case in which the selective epitaxial growth process is performed, when the amorphous region 30A and the crystalline region 30B are simultaneously exposed, the fourth liner layer 32 is grown at a high speed in the amorphous region 30A as compared with the crystalline region 30B. The amorphous region 30A may be a growth region and the crystalline region 30B may be a non-growth region. Thus, the silicon layer may be selectively grown using selectivity between the growth region and the non-growth region.

The selective epitaxial growth process is performed as described above, so that the silicon layer with a certain thickness is grown. For example, since the fourth liner layer 32 is grown on the amorphous region 30A, the amorphous region 30A is thicker than the crystalline region 30B. The fourth liner layer 32 is formed with substantially the same thickness as that of the third liner layer 30. Preferably, the fourth liner layer 32 is formed with a thickness of 100 Å or less. Therefore, for example, when the third liner layer has a thickness of 100 Å and the fourth liner layer has a thickness of 100 Å, the total thickness of the silicon layer in the crystalline region 30B is 100 Å, but the total thickness of the silicon layer in the amorphous region 30A is 200 Å.

Referring to FIG. 2I, the fourth liner layer 32 and the third liner layer are selectively removed until the crystalline region 30B is removed. In order to remove the crystalline region 30B, a blanket removal process 33 is performed. That is, the fourth liner layer 32 and the third liner layer are removed without a mask, and more particularly, without using a photoresist layer. The blanket removal process 33 uses a cleaning or etching process. The cleaning or etching process may be a dry method or a wet method. For example, in the case of using a dry etch process, an etch-back process is used.

The blanket removal process 33 is performed until the crystalline region 30B is removed. Although the crystalline region 30B is removed, the amorphous region 30A with a certain thickness remains at a specific position. When the third liner layer and the fourth liner layer have substantially the same thickness, only the amorphous region 30A remains, as shown in FIG. 2I. However, when the fourth liner layer has a thickness larger than that of the third liner layer, the amorphous region 30A and a part of the fourth liner layer 32 may remain.

The above-mentioned blanket removal process 33 takes advantage of the difference in thickness, and removes the crystalline region 30B with a thin thickness, while leaving at least a part of the amorphous region 30A, which serves as an etch barrier in a subsequent process.

Referring to FIG. 23, the second sacrificial patterns 28 on one of the sidewalls of the body 24 is removed, so that a gap G is formed between of the third sacrificial pattern 29 and the second liner pattern 27A. The second sacrificial pattern 28 is removed using a wet etch process, so that only one sidewall of the body 24 has a second sacrificial pattern 28A remaining thereon.

Referring to FIG. 2K, a cleaning process is performed in order to expose a part of the sidewall of the body 24.

The cleaning process includes a wet cleaning process. The wet cleaning process may use HF, buffered oxide etchant (BOE), and/or the like. Using the wet cleaning process, it is possible to selectively remove the first liner pattern 25A without damaging the first sacrificial pattern 26B, the second sacrificial pattern 28A, and the second liner pattern 27A. When a part of the first liner pattern 25A is removed, the third sacrificial pattern 29 is also removed.

Hereinafter, the first liner pattern 25A, the second liner pattern 27A, the first sacrificial pattern 26B, and the second sacrificial pattern 28A may be collectively referred to as a ‘gap-fill layer’. The gap-fill layer covers both sides of the body 24 and partially gap-fills the trench 23. The gap-fill layer provides an open part 34 that exposes a part of the sidewall of one of the bodies 24. Since the open part 34 exposes a part of the sidewall of the body 24, it is also called a sidewall open part or a side contact. The open part 34 may provide a contact through which a conductive material such as a buried bit line makes contact with the body 24.

Referring to FIG. 2L, the amorphous region 30A is removed. At this time, since the amorphous region 30A and the first sacrificial pattern 26B include polysilicon, they may be simultaneously removed.

The remaining second sacrificial pattern 28A is also removed.

As described above, the deposition speed difference through the crystallization difference and the selective growth process is used, so that it is possible to easily form an etch barrier for forming an open part. Consequently, it is possible to overcome the limitation of an interval of a three-dimensional structure using a one-time ion implantation process.

In accordance with an exemplary embodiment of the present invention, using a process for increasing a thickness through the crystallization difference and the selective growth process and removing the thickness, it is possible to form an etch barrier, thereby opening the sidewall of a three-dimensional structure.

As a result, it is possible to form an open part, which may be used as a contact and the like, with uniform depth and position. Also, the process of forming the open part may be implemented when fabricating a highly integrated or miniature semiconductor device.

While the present invention has been described with respect to the specific embodiments, it will be apparent to those skilled in the art that various changes and modifications may be made without departing from the spirit and scope of the invention as defined in the following claims.

1. A method for fabricating a semiconductor device, comprising:
forming a first silicon layer including an amorphous region and a crystalline region on a structure;
forming a second silicon layer on one of the amorphous region and the crystalline region through a selective epitaxial growth process;
removing the second silicon layer and the first silicon layer until one of the regions of the first silicon layer is removed, thereby forming an etch barrier; and
etching using the etch barrier to form an open part that exposes a part of a sidewall of the structure.

2. The method of claim 1, wherein, in the forming of the first silicon layer, the amorphous region and the crystalline region are formed using a selective impurity ion implantation process.

3. The method of claim 2, wherein the selective impurity ion implantation process is performed using a tilt ion implantation process.

4. The method of claim 1, wherein the selective epitaxial growth process forms the second silicon layer only on the amorphous region.

5. The method of claim 1, wherein the removing of the second silicon layer and the first silicon layer is performed using a dry etch process or a wet etch process.

6. The method of claim 1, wherein the thickness of the second silicon layer is the same as the thickness of the first silicon layer.

7. The method of claim 1, further comprising:
removing a sacrificial pattern to expose a portion of one sidewall of a body.

8. The method of claim 7, wherein the removing of the sacrificial pattern comprises a wet etch process that uses the remaining portion of the first silicon layer as an etch barrier.

9. A method for fabricating a semiconductor device, comprising:
forming a structure having first surfaces at a height above a second surface, which is provided between the first surfaces;
forming a first silicon layer on the structure;
performing a tilt ion implantation process on the first silicon layer to form a crystalline region and an amorphous region;
forming a second silicon layer on the amorphous region;
removing the second silicon layer and the first silicon layer until a part of the second surface is exposed, thereby forming an etch barrier; and
etching using the etch barrier to form an open part that exposes a part of a sidewall of the structure.

10. The method of claim 9, wherein the forming of the second silicon layer is performed by a selective epitaxial growth process to selectivity grow the second silicon layer based on a difference in crystallization between the crystalline region and the amorphous region.

11. The method of claim 9, wherein the first silicon layer includes a polysilicon layer.

12. The method of claim 9, wherein the first silicon layer includes an undoped polysilicon layer.

13. The method of claim 9, wherein the forming of the etch barrier is performed using a dry etch process or a wet etch process.

14. The method of claim 9, wherein the forming of the structure comprises:
etching a semiconductor substrate to form a plurality of bodies separated by a trench;
forming a liner layer that covers both sidewalls of the bodies and a bottom surface of the trench;
forming a first sacrificial layer on the liner layer, which is recessed to partially gap-fill the trench;
forming a second sacrificial layer that covers a sidewall of the liner layer; and
forming a third sacrificial layer on the first sacrificial layer, which is recessed to partially gap-fill the trench.

15. The method of claim 14, wherein the liner layer has a dual structure of an oxide layer and a nitride layer.

16. The method of claim 14, wherein the first sacrificial layer includes polysilicon, the second sacrificial layer includes a titanium nitride layer, and the third sacrificial layer includes an oxide layer.

17. The method of claim 14, further, after the forming of the open part, comprising:
forming a buried bit line that partially fills the trench to be connected to the sidewall of the structure through the open part.
